(19) United States
(12) Patent Application Publication
(10) Pub. No.: US 2013/0240981 A1
(43) Pub. Date: Sep. 19, 2013

(54) TRANSISTOR ARRAY WITH A MOSFET AND MANUFACTURING METHOD

(71) Applicant: INFINEON TECHNOLOGIES AUSTRIA AG, Villach (AT)

(72) Inventors: Michael HUTZLER, Villach (AT); Hans-Joachim SCHULZE, Taufkirchen (DE); Ralf SIEMIENIEC, Villach (DE)

(21) Appl. No.: 13/867,215

(22) Filed: Apr. 22, 2013

Related U.S. Application Data
(63) Continuation-in-part of application No. 13/092,546, filed on Apr. 22, 2011.

(30) Foreign Application Priority Data
Apr. 20, 2012 (DE) 102012206605.5

(51) Int. Cl. H01L 29/78; H01L 29/66

(52) U.S. Cl. CPC H01L 29/7827; H01L 29/66666
USPC 257/328; 438/268

(57) ABSTRACT

Disclosed are a semiconductor device and a method for producing a semiconductor device. A MOSFET may have a source region, a drift region and a drain region of a first conductivity type, a body region of a second conductivity type disposed between the source region and the drift region, and a gate electrode disposed adjacent to said body region. The gate electrode may be isolated from the body region by a dielectric, and have a source electrode contacting the source region and the body region. A self-locking JFET, associated with the MOSFET, may have a channel region of the first conductivity type, the channel region connected between the source electrode and the drift region, and coupled to and adjacent the body region.

### RELATED APPLICATIONS

This application claims priority benefit of German Patent Application 102012206605.5, which was filed on Apr. 20, 2012. Furthermore, this application is a Continuation in Part of U.S. patent application Ser. No. 13/092,546, which was filed on Apr. 22, 2011. The entire contents of the German and U.S patent applications are incorporated herein by reference.

### BACKGROUND

Embodiments of the present invention relate to a device comprising a MOSFET (Metal Oxide Semiconductor Field-Effect transistor), and in particular a device comprising a MOSFET transistor and a self-locking JFET (Junction Field-Effect Transistor).

MOSFETs (Metal Oxide Semiconductor Field-Effect transistor), particularly power MOSFETs are widely used as an electronic switch for switching electrical loads or electrical switches in all types of switching converters. A power MOSFET may include a drain region, a drift region, which adjoins the drain region and a source region, each having a first conductivity type, and disposed between the drift region and the source region of the body region of a second conductivity type. A gate electrode is used for controlling a conducting channel in the body region between the source region and the drift region. The source region is electrically connected to a source electrode, which is also connected to the body region and the drain region is electrically connected to a drain electrode.

A MOSFET can be used in a forward polarized state (also known as: forward biased state) and a reverse polarity condition (also known as: reverse biased state). In the forward polarity condition there is a voltage between the drain electrode and the source electrode so that a pn junction between the body region and the drift region is polarized in the reverse direction. In the forward polarity condition the MOSFET can be turned on and off by applying a suitable electrical potential to the gate electrode. In the reverse polarity condition of the MOSFET, the pn junction between the body region and the source region is polarized in the forward direction, so that the MOSFET operates as a diode poled in the reverse state, commonly referred to as a body diode.

In many applications, such as in applications in which the MOSFET is used as a switch which periodically switches an inductive load, there are periods of time during which the MOSFET is reverse biased, so that the body diode conducts a current. The losses occur when a current flows through the MOSFET in the reverse direction flows are dependent on the current and the forward voltage of the body diode. The forward voltage of the body diode, the voltage that is required for the body diode conducts a current. In a silicon MOSFET, the forward voltage is approximately 0.7 V.

### SUMMARY

Implementations provide a semiconductor device with a MOSFET having reduced losses during operation in the reverse direction, a MOSFET with reduced losses during operation in the reverse direction, a method of manufacturing a semiconductor device comprising a MOSFET, and a JFET.

A first embodiment relates to a semiconductor device comprising a MOSFET comprising a source region, a drift region and a drain region of a first conductivity type, a body region disposed between the source region and the drift region of a second conductivity type and a gate electrode arranged adjacent to the body region, and which is insulated with respect to the body region by a dielectric. A source electrode may contact the source region and the body region. The semiconductor device further comprises a self-locking JFET with a channel region of first conductivity type adjacent to the source electrode of the drift region which extends to the body region.

A second embodiment relates to a MOSFET having a semiconductor body having a source region, a drift region and a drain region of a first conductivity type and a body region disposed between the source region and the drift region of a second conductivity type. The MOSFET also includes a gate electrode, which is adjacent to the body region and which is dielectrically isolated by a gate dielectric, and a source electrode contacting the source region and the body region. A channel region of the first conductivity type extending from the source electrode to the drift region adjacent to the body region such that a pn junction between the body region and the channel region is formed. A doping concentration of the body region and a width of the channel region are selected such that an intrinsic depletion region pinches off the channel region when the MOSFET in a non-biased condition (also known as: unbiased state).

A third embodiment relates to a method for producing a semiconductor device. The method comprises providing a semiconductor body with a drift region of a first conductivity type, a region adjoining the drift region in a vertical direction of the semiconductor body, the body region of which is complementary to the first conductivity type said second conductivity type, a region adjacent to the body region in the vertical direction of the semiconductor body, the source region of the first conductivity type and a gate electrode which is disposed adjacent to the body region and dielectrically isolated from the body region by a gate dielectric. The method also includes forming a channel region in the body region spaced from the gate dielectric, wherein the channel region extends from the source region down to the drift region, the production of at least one trench in the source region, the body region and the channel region such that a first sidewall of said trench adjacent to the body region and the first side wall opposite second sidewall of the trench in the channel region, forming a depletion control region of the second conductivity type adjacent to the trench at least in the channel region and spaced from the source region, and forming a source electrode in the trench.

Embodiments are described below with reference to drawings. The drawings are not necessarily to scale. Like reference numerals designate like parts throughout the drawings. The drawings serve to illustrate the basic principle, so that only those features are shown which are necessary for the understanding of the basic principle. Features are shown in different embodiments may be combined with features of other embodiments, even if this is not explicitly mentioned hereinafter.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items.

For this discussion, the devices and systems illustrated in the figures are shown as having a multiplicity of components. Various implementations of devices and/or systems, as described herein, may include fewer components and remain within the scope of the disclosure. Alternately, other implementations of devices and/or systems may include additional components, or various combinations of the described components, and remain within the scope of the disclosure.

FIG. 1 schematically shows a vertical cross-sectional view of a semiconductor device having a MOSFET and a JFET in accordance with a self-conducing the first embodiment.

FIG. 2 shows a detail of the semiconductor device shown in FIG. 1.

FIG. 3 schematically shows a vertical cross-sectional view of a semiconductor device having a MOSFET and a self-locking JFET, each having a cellular structure according to a first embodiment.

FIG. 4 schematically shows a horizontal cross-sectional view of a semiconductor device, wherein the MOSFET comprises a plurality of strip-shaped cells.

FIG. 5 shows schematically a horizontal cross-sectional view of a semiconductor device, wherein the MOSFET comprises a plurality of rectangular cells.

FIG. 6 schematically illustrates a horizontal cross-sectional view of a semiconductor device, wherein said MOSFET comprises a plurality of hexagonal cells.

FIG. 7 schematically shows a horizontal cross-sectional view of another example of a semiconductor device, wherein the MOSFET comprises a plurality of rectangular cells.

FIG. 8 shows schematically a horizontal cross-sectional view of another example of a semiconductor device, wherein the MOSFET comprises a plurality of hexagonal cells.

FIG. 9 schematically shows a vertical cross-sectional view of a semiconductor device having a MOSFET and a JFET in accordance with a self-locking second embodiment.

FIG. 10 shows a modification of the semiconductor device shown in FIG. 7.

FIG. 11 schematically shows a vertical cross-sectional view of a semiconductor device having a MOSFET and a JFET in accordance with a self-locking third embodiment.

FIG. 12 schematically shows a vertical cross-sectional view of a semiconductor device having a MOSFET and a self-locking, according to another embodiment of JFET.

FIGS. 13A-13E illustrate a method of manufacturing a semiconductor device having a MOSFET and a JFET using a vertical cross-sections through a semiconductor body during various process steps.

FIG. 14 shows a vertical cross section of a semiconductor device according to another embodiment which has been prepared by a modification of the method of FIG. 13.

FIG. 15 shows a vertical cross section of a semiconductor device prepared by a further modification of the method of FIGS. 13A-13E.

FIG. 16 shows a vertical cross section of a semiconductor device prepared by a further modification of the method of FIG. 13.

### DETAILED DESCRIPTION

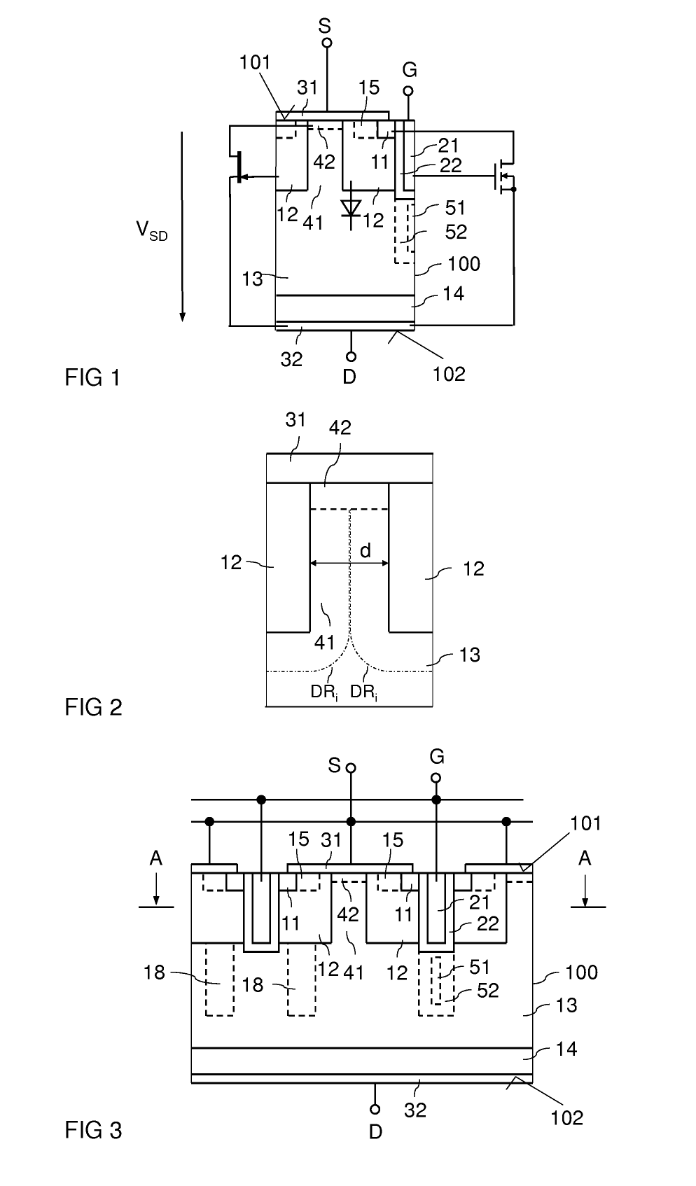

FIG. 1 illustrates schematically a semiconductor device comprising a MOSFET and a self-locking JFET. FIG. 1 illustrates a vertical cross-sectional view of a semiconductor body 100, wherein a MOSFET and self-locking JFET are implemented in the active areas. The semiconductor device includes the semiconductor body 100, a first surface 101 and second surface 102 opposite the first surface 101. The semiconductor body 100 may include a conventional semiconductor material, such as silicon (Si), silicon carbide (SiC), gallium arsenide (GaAs). FIG. 1 illustrates a vertical cross-section through the semiconductor body 100, that is a cross-section in a vertical section plane that is perpendicular to the first and second surfaces 101, 102.

The MOSFET comprises a source region 11, a drift region 13 and a drain region 14, each of a first conductivity type and a body region 12 of a second conductivity type that is complementary to the first conductivity type. The body region 12 is disposed between the source region 11 and the drift region 13, so that the body region 12 separating the source region 11 from the drift region 13. The drift region 13 is disposed between the body region 12 and the drain region 14, wherein a pn junction between the body region 12 and the drift region 13 is formed.

The MOSFET also includes a gate electrode 21 which is disposed adjacent to the body region 12 and extends from the source region 11 to the drift region 13. The gate electrode 21 is over the source region 11, the body region and the drift region 13 dielectrically isolated by a gate dielectric 22. In conventional manner, the gate electrode 21 serves to control a conductive channel in the body region 12 between the source region 11 and the drift region 13.

The MOSFET can be configured as n-channel MOSFET or p-channel MOSFET. In an n-type MOSFET, the source region 11, the drift region 13 and the drain region 14 are n-doped, whereas the body region 12 is p-doped. In a p-type MOSFET, the source region 11, the drift region 13 and the drain region 14 is p-doped, whereas the body region 12 is n-doped. Dopant concentrations of the source region 11 and drain region 14 are, for example, in a range between 10¹⁹ (E19) cm⁻³ und 10²¹ (E21) cm⁻³. The doping concentration of the drift region 13 is, for example in a range between 10¹³ (E13) cm⁻³ und 2·10¹⁷ (2E17) cm⁻³ and the doping concentration of the body region 12 is, for example, in a range between 1016 (E16) cm-3 and 1018 (E18) cm-3.

The source region 11 and body region 12 are electrically connected to a source electrode 31 and the drain region 14 is electrically connected to a drain electrode 32. The source electrode 31 and the drain electrode 32 may have a conventional electrode material, such as a highly doped polysilicon, or a metal such as aluminum, copper, titanium, tungsten, etc.

The MOSFET illustrated in FIG. 1 is formed as a vertical MOSFET. In this case, the source region 11 and drain region 14 in the vertical direction of the semiconductor body 100 are spaced apart from one another. The source electrode 31 is arranged in the region of the first surface 101 of the semiconductor body 100 and the drain electrode 32 is disposed in the second surface 102 of the semiconductor body 100. However, the formation of the MOSFET is only an example of a vertical MOSFET. The previously described also applicable to a lateral MOSFET.

The MOSFET of FIG. 1 is a trench MOSFET. In this MOSFET, the gate electrode 21 is arranged in a trench which extends from the surface 101 in the area of the source region 11 by the body region 12 into the drift region 13. However, any other conventional gate configuration may be used, such as a gate configuration having a planar gate electrode, which is disposed above the first surface 101 of the semiconductor body 100.

Optionally, the MOSFET comprises a field electrode 51 which is arranged in the drift region 13 and which is opposite to the drift region 13 dielectrically isolated by a field electrode dielectric 52. Typically, the field electrode dielectric 52 is thicker than the gate dielectric 22. The field electrode dielectric 52 may be a conventional dielectric material such as an oxide, a nitride, etc. The field electrode 51 can be arranged below the gate electrode 21 (as shown in FIG. 1). However, it is also possible to arrange the pad electrode 51 in a separate trench spaced in a lateral direction of the semiconductor body 100. The field electrode 51 can be electrically connected to the gate electrode 21 or to the source electrode 31. One terminal of the field electrode 51 connected to the gate electrode 21 or the source electrode 31 of the semiconductor body 100.

Referring to FIG. 1, the semiconductor device further comprises a channel and a channel region 41 of first conductivity type. The channel region 41 is electrically connected to the source electrode 31 and extends adjacent to the body region 12 from the source electrode 31 and to the drift region 13, so that a pn-junction between the channel region 41 and the body region 12 is formed.

The channel region 41 and the portion of the body region 12 that is adjacent to the channel region 41 form a JFET (Junction Field-Effect Transistor). In FIG. 1, the electrical circuit symbols of these MOSFET and JFET components are shown, except the active regions. For purposes of explanation is assumed that the MOSFET is an n-channel MOSFET and the JFET is an n-type JFET.

The JFET is a self-locking or normal-off JFET. This means that the channel region 41 is pinched off by an intrinsic depletion region when the JFET is at a non-biased state. The JFET is located in a non-biased state, if the MOSFET is in a non-biased state, and the MOSFET is located in a non-biased state when a voltage between a drain terminal D connected to the drain electrode 32, and a source terminal S connected to the source electrode 31 is zero, and when a voltage between the gate terminal G connected to the gate electrode 21, and the source terminal S is zero or negative. The intrinsic depletion region is the depletion region, which is present between the body region 12 and the channel region 41 along the pn junction formed between the body region 12 and the channel 41. When a pn junction is present with the first doped region such as the body region 12, and a second doped region, such as the channel region 41, the width W of the depletion region (or a space charge zone) formed in the second region (such as the channel region 41) is given by (cf. SZE, “Physics of Semiconductor Devices”, Third edition, 2007, Wiley and Sons, page 83):

$$w = \sqrt{\frac{2 {ɛ}_{S} {ψ}_{bi}}{q} \frac{{N}_{12}}{{N}_{41} ( {N}_{41} + {N}_{12} )}} . \qquad ( 1 a )$$

Here, w is the width of the depletion region, at yield the dielectric constant of the pn junction forming the doped region, Ψ_{bi} the diffusion potential, q is the elementary charge, N₁₂, the doping concentration of the first doped region such as the body region 12, N₄₁ and the doping concentration of said second doped region, such as the channel 41. The diffusion potential Ψ_{bi} depends on the kind of semiconductor material and the doping concentration. At room temperature (300K), the diffusion potential in silicon (Si) is between about 0.3 V and 0.5 V, if the dopant concentration is between 10¹⁴ (E14)cm⁻³ and 10¹⁸ (E18)cm⁻³ (see, SZE, “Physics of Semiconductor Devices”, Third edition, 2007, Wiley and Sons, page 92). The width of the depletion region is a width in a direction perpendicular to the pn junction.

If the channel region 41 has a substantially lower doping concentration than the body region 12, then the width W of the depletion region (the space charge region) in the channel region 41 is approximately given by:

$$w = \sqrt{\frac{2 {ɛ}_{S}}{q} \frac{{ψ}_{bi}}{{N}_{41}}} \qquad ( 1 b )$$

(see, “Physics of Semiconductor Devices”, Third Edition, 2007, Wiley and Sons, page 83).

The JFET has a direction of current flow. The current flow direction corresponding to the direction in which the channel region 41 extends along the body region 12 from the source electrode 31 to the drift region of 13. In the embodiment illustrated in FIG. 1, this current flow direction corresponds to the vertical direction of the semiconductor body 100. The body region 12 is arranged adjacent in a direction perpendicular to the direction of current flow to the channel region 41. The direction perpendicular to the direction of current flow is a lateral or horizontal direction of the semiconductor body 100 in the semiconductor device shown in FIG. 1. The intrinsic depletion region interrupts the lacing channel 41 or the channel 41 completely, when the intrinsic depletion region extends in the direction perpendicular to the direction of current flow through the channel region 41 completely therethrough. This will be explained below with reference to FIG. 2, in which the channel region 41 and regions adjacent thereto are shown in detail.

Referring to FIG. 2, the channel 41 has a size (width) up to d. The d is the dimension of the channel width of the channel 41 in the direction perpendicular to the direction of current flow. In particular, the smallest dimension of the channel 41 in the direction of the channel width d is perpendicular to the direction of current flow. In the embodiments shown in the FIGS. 1 and 2, the body region 12 is adjacent to opposite sides of the channel to 41. In this case, the intrinsic depletion region under the channel region 41 then stops completely if the width of the depletion region is at least half the length d of the channel, that is, when:

w≧d/2 (2).

In one embodiment, the channel width d and the width of the intrinsic depletion region are selected such that the channel width d is between 1.5 times and less than 2 times the width w of the intrinsic depletion region, that 1.5w≦d<2w. The channel width d is, for example, between 0.1 μm und 0.8 μm.

In FIG. 2, DRᵢ denotes the limit of the intrinsic depletion region. In this embodiment, a width w corresponding to depletion of the intrinsic region of the half of the channel width d so that the intrinsic depletion region, originating from the pn junctions on either side of the channel region 41, the channel region 41 completely cuts off.

Referring to FIGS. 1 and 2, a contact region 42 of the first conductivity type channel region 31 may be arranged between the source electrode 41 and the source electrode 31 and serve to connect the channel region 41. The contact region 42 is used in particular to produce an ohmic contact between the source electrode 31 and the channel region 41. A doping concentration of the contact region 42 is higher than the doping concentration of the channel region 41. In one embodiment, the doping concentration of the contact region 42 is such that between the source electrode 31 and the contact region 42, an ohmic contact is formed. The absolute impurity concentration of the contact region 42 is for example between 10¹⁹ (E19) cm⁻³ und 10²¹ (E21) cm⁻³. The intrinsic depletion region is also present along the pn junction between the contact area 42 and the body region 12. However, the depletion region does not extend as far into the contact region 42, as in into the channel region 41, such that the depletion region is not shown in the contact region 42 in FIG. 2.

The operation of the semiconductor device according to FIG. 1 is explained below. For purposes of explanation, it is assumed that the MOSFET and the JFET are each n-type devices. However, this is merely an example. The operation principle is also applicable to an arrangement having a p-type MOSFET and a p-type JFET.

The operation of the semiconductor device of FIG. 1 is determined by the MOSFET. The MOSFET is located in a forward poled state when a positive voltage between the drain terminal D and the source S is applied. In the forward polarity condition of the MOSFET, in a conventional manner, is to be switched on and off by a suitable driving potential to the gate terminal G, wherein the MOSFET is in an on state (turned on) when the voltage applied to the gate electrode G is of suitable drive potential that a conducting channel (inversion channel) is formed in the body region between the source region 11 and the drift region 13. In a corresponding way, the MOSFET is in the off-state (off) if the voltage applied to the gate terminal G of drive potential is not sufficient to produce a conductive channel in the body region 12. Typically, an n-type silicon MOSFET is in its ON state when a gate-source voltage is above a threshold value, wherein a strong inversion in the body region along the gate dielectric 22 is employed, and, in its off state if the gate-source voltage is below this voltage.

When the MOSFET is biased forwardly and is in its on state, a current flows between the source region 11 and drain region 14 and flows through the conductive channel in the body region 12 and the drift region 13. In particular, n-type charge carriers flow (electrode) of the source region 11 through the conductive channel along the gate dielectric 22 and the drift region 13 to the drain region 14. In an n-type MOSFET, the drift region 13 has a higher electric potential than the body region 12, which is connected to the source electrode 31, when the MOSFET is in its ON state. Therefore, the pn junction between the body region 12, on one hand, and the channel 41 and drift region 13, on the other hand, are polarized in the reverse direction so as to extend the depletion layer in a region below the channel 41 deeper into the drift region 13. The conductive channel along the gate dielectric 22 enables a current flow through this pn junction between the body region 12 and the drift region 13 when the MOSFET is in its ON state. Since the channel region 41 is completely depleted by an intrinsic depletion region, there is no further propagation of the depletion region in the channel region 41. Accordingly, the channel region 41 is then cut off or interrupted, when the MOSFET is in its ON state.

When the MOSFET is biased forwardly and is in its off-state, the conductive channel of the gate dielectric 22 is interrupted, and a depletion region propagates within the drift region 13 starting from the pn junction between the body region 12 and the drift region 13. The channel 41 of the JFET is interrupted in this state.

The doping concentration of the channel region 41 and the doping concentration of the drift region 13 correspond. In this case, the doping concentration of the channel region 41 is for example between 10¹³ (E13) cm⁻³ und 2·10¹⁷ (2E17) cm⁻³, in particular between 10¹³ (E13) cm⁻³ und 10¹⁵ (E15) cm⁻³, and the intrinsic depletion region of the pn junction between the body region 12 and the channel region 41 corresponds to an intrinsic depletion region at the pn junction between the body region 12 and the drift region 13. It is also possible to choose the impurity concentration of the channel region 41 so that it is different from the dopant concentration of the drift region 13. The doping concentration of the channel region 41 may be higher or lower than the doping concentration of the drift region 13. However, the doping concentration of the channel region 41 and the body region 12 are in each case matched to one another and to the channel width d.

The (n-type) MOSFET is reverse biased when a positive voltage between the source S and drain D is applied, i.e. if the source S has a positive potential relative to the potential at the drain terminal D. In this reverse polarity condition a body diode of the MOSFET is parallel to the JFET. The body diode is formed by the body region 12 and the drift region 13. The electrical circuit symbol of the body diode is also shown in FIG. 1. A current can flow through the body diode when a voltage between the source S and the drain terminal D is higher than a forward voltage of the body diode, that is, when a voltage between the source S and the D drain connection biases the pn junction between the body region 12 and the drift region 13 in the flow direction. The forward voltage is usually about 0.7 V in a silicon diode.

In the MOSFET according to FIG. 1, a current between the source S and drain D already flows then through the JFET when a voltage V_{SD} is located between the source S and drain D below the forward voltage of the body diode, and for the following reason: If the MOSFET is in a non-biased state, the intrinsic depletion region constricts the channel region of the JFET 41. When a positive voltage between the body region 12 and the channel region is applied 41, which will be the case where the MOSFET is reverse biased, that reduces a width (length) of the depletion region or space charge zone along the pn junction between the body region 12 and the channel region 41, so that (in the example n-doped) the channel region 41 is opened between the source electrode 31 and the drift region 13 (electrically conducting). The voltage required to open the channel region 41 is dependent on how much the depletion regions extending from the pn junctions on either side of the channel region 41 overlap each other. If this depletion regions are such that a width w of the intrinsic depletion region is between 0.5 and 0.6 d, this voltage is a positive voltage, which is significantly below the forward voltage of the body diode. Therefore, positive voltages, which are below the forward voltage of the body diode, are sufficient to open the channel region 41, i.e. conducting the JFET.

The JFET, having the channel region 41 adjacent to the body region 12 and is controlled by the body region 12 and the source electrode 31, and thus helps to reduce the reverse voltage is required for the MOSFET conduct current in their reverse direction. Further, the reverse recovery behavior of the MOSFET is improved for the following reasons: Unlike the body diode the body diode is of the JFET is a unipolar device, so that primarily majority carrier flow through the drift region 13 when the MOSFET is biased in the reverse direction, and when the reverse voltage is below the forward voltage. Therefore, no or only a few minority carriers exist in the drift region 13. In conventional MOSFETs in which the body diode is active when the MOSFET is reverse biased, these minority carriers must be removed from the drift region before the MOSFET turns off if a MOSFET reverse pole end voltage is applied. This removal of the minority carriers caused a delay time, which can lead to increased losses. This is largely prevented in the aforementioned arrangement.

Referring to FIG. 3, the MOSFET having a plurality of identical transistor cells which are connected in parallel, may be formed. Each of these transistor cells comprising a source region 11, a body region 12, a gate electrode 21 and a gate dielectric 22, as well as, optionally, a field electrode 51 and a field electrode dielectric 52 The drift region 13 and the drain region 14 are common to the individual transistor cells, i.e. the individual transistor cells share the drift region 13 and the drain region 14. Source regions 11 and body regions 12 are connected to a common source electrode 31 and a common source terminal S and gate electrodes 21 are each connected to a common gate terminal G. In this embodiment, the channel region 41 and the optional area of contact of a JFET 42 are disposed between the body regions 12 of two adjacent transistor cells. The operating principle of the MOSFET according to FIG. 1 has been explained previously, and that principle applies to the MOSFET according to FIG. 3 in a corresponding manner.

Alternatively, or in addition to a field electrode 51, the individual cells may have a compensating transistor area 18, which is arranged in the drift region 13 which is doped complementarily to the drift region 13 and which is connected to the body region. Such compensation regions 18 are shown in FIG. 3 in the left portion of the cross sectional view. A doping concentration of dopant compensation areas 18 corresponds to, for example, a doping concentration of the drift region 13.

In the embodiments described below, where the field electrodes are shown 51, also each compensation regions 18 are shown as an alternative or as an additional measure to the field electrodes 51.

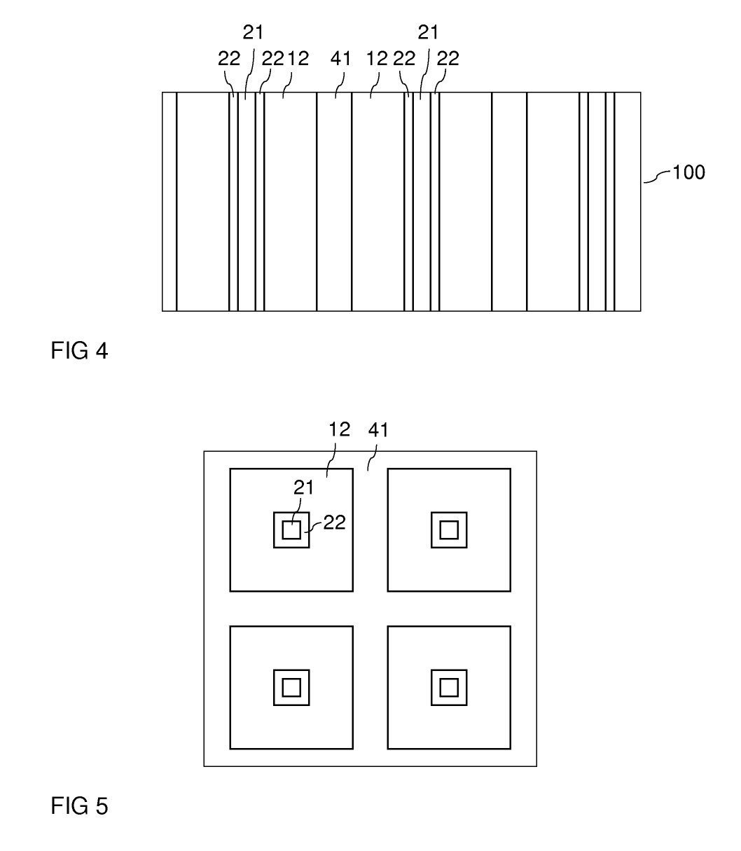

A single transistor cell may have one of several different shapes or geometries. The shape or geometry of a transistor cell is mainly defined by the shape of the associated source region 11 and body region 12. Various embodiments are described below with reference to FIGS. 4 through 7. FIGS. 4 to 7 each show horizontal cross-sectional views (in a section plane AA) of the semiconductor body 100, in the cells of a MOSFET transistor, and channel regions 41 of JFETs are disposed.

FIG. 4 shows an embodiment in which the individual transistor cells are strip-shaped. In this embodiment, the source regions 11, body regions 12 and the gate electrode 21 have a strip-shaped or elongated geometry. Correspondingly, the channel regions 41, which are arranged between two adjacent body regions 12, also of an elongated or strip-shaped geometry.

In the embodiment shown in FIG. 5 shows the source regions and the body regions have a rectangular geometry. In this case there is only one channel of the JFET region 41, with individual sections of this channel region 41 disposed between the two body regions 12 of two adjacent transistor cells. In the horizontal plane, the channel region 41 has the shape of a rectangular grid.

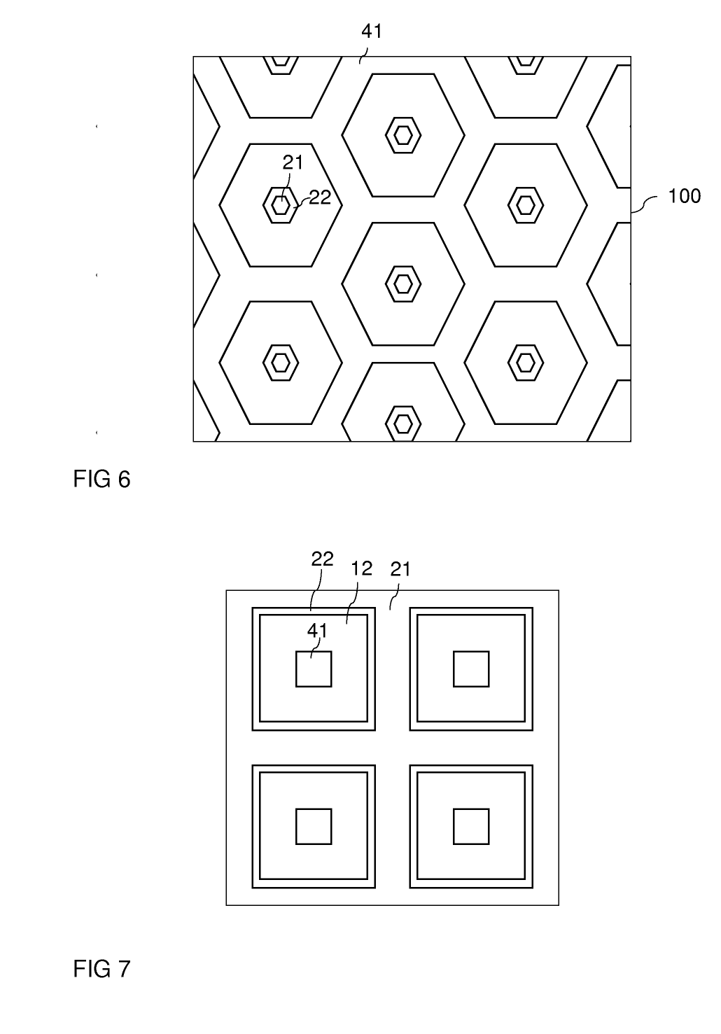

In the embodiment shown in FIG. 6, the source regions 11 and the body regions 12 have a hexagonal geometry. In this case there is only one channel region of the JFET 41, wherein individual sections of the channel region 41 are disposed between the two body regions 12 of two adjacent transistor cells. In the horizontal plane, the channel region 41 has the shape of a hexagonal lattice.

FIG. 7 shows a horizontal cross-section through the semiconductor body of a semiconductor device 100 according to another embodiment. In this embodiment, the gate electrode 21 has the shape of a rectangular grid that separates the body regions 12 from other single transistor cells. The channel regions 41 are columnar in this embodiment, each channel region 41 is surrounded in lateral direction by a body region 12.

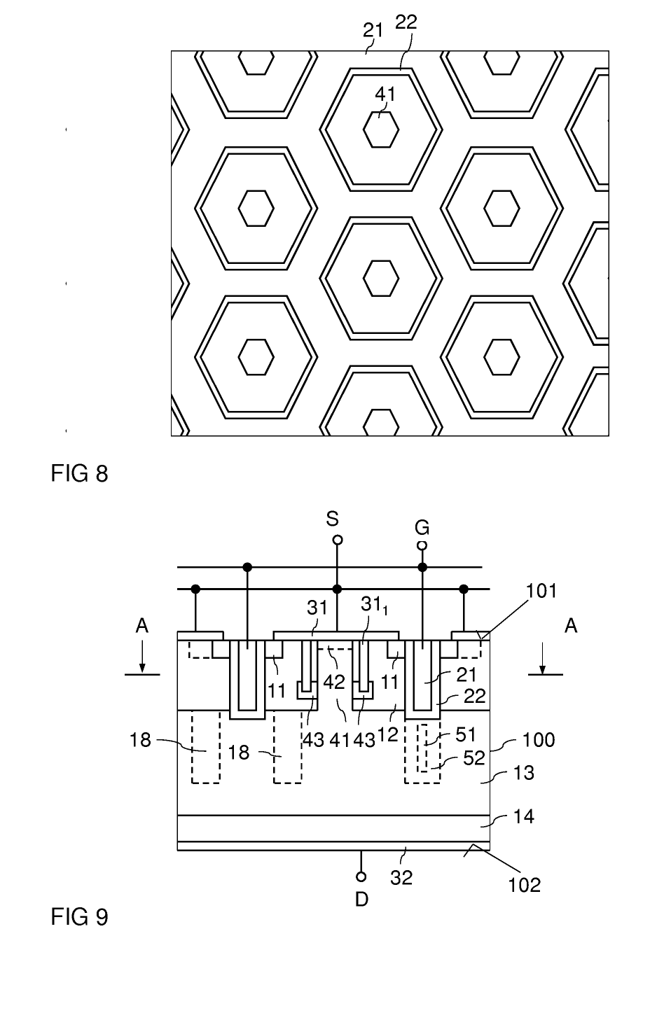

In the exemplary embodiment shown in FIG. 8, the single channel regions 41 are columnar. In this embodiment, the gate electrode 21 adjacent to the gate dielectric 22 has the shape of a hexagonal lattice.

FIG. 9 shows a vertical cross-sectional view of a semiconductor device having a MOSFET and a JFET. The assembly of FIG. 7 is based on the arrangement according to FIGS. 1 and 3. Compared to the arrangement according to FIGS. 1 and 3, the assembly of FIG. 7 additionally includes control a depletion region (channel control region) 43 of the second conductivity type. Control the depletion region 43 is disposed adjacent to the body region 12, but more highly doped than the body region 12. An impurity concentration of the depletion region 43 is for example between 5 times and 50 times the impurity concentration of the body region 12. The depletion region 43 forms a pn junction with the channel region 41 and is spaced apart from the current direction to the contact area optional 42. The depletion region 43 is electrically connected to the source electrode 31, the source electrode 31 has an electrode portion 31₁ that extends into the semiconductor body 100 and to the channel control field 43. In the embodiment illustrated in FIG. 9, the depletion region 43 is spaced apart from the first surface 101 of the semiconductor body 100. The spacing is for example between 0.1 μm and 3 μm.

In the device according to FIG. 9, the impurity concentration of the depletion region 43 defines the cutoff voltage, together with control of the impurity concentration of the channel region, of the JFET 41. The doping concentration of the body region 12 defines the threshold voltage of the MOSFET. The doping concentrations of the depletion control region 43 and the body region 12 can be independently selected, so that the cutoff voltage and/or the channel width of the JFET will be independent of a doping concentration of the body region 12 and thus set independently of the threshold voltage of the MOSFET.

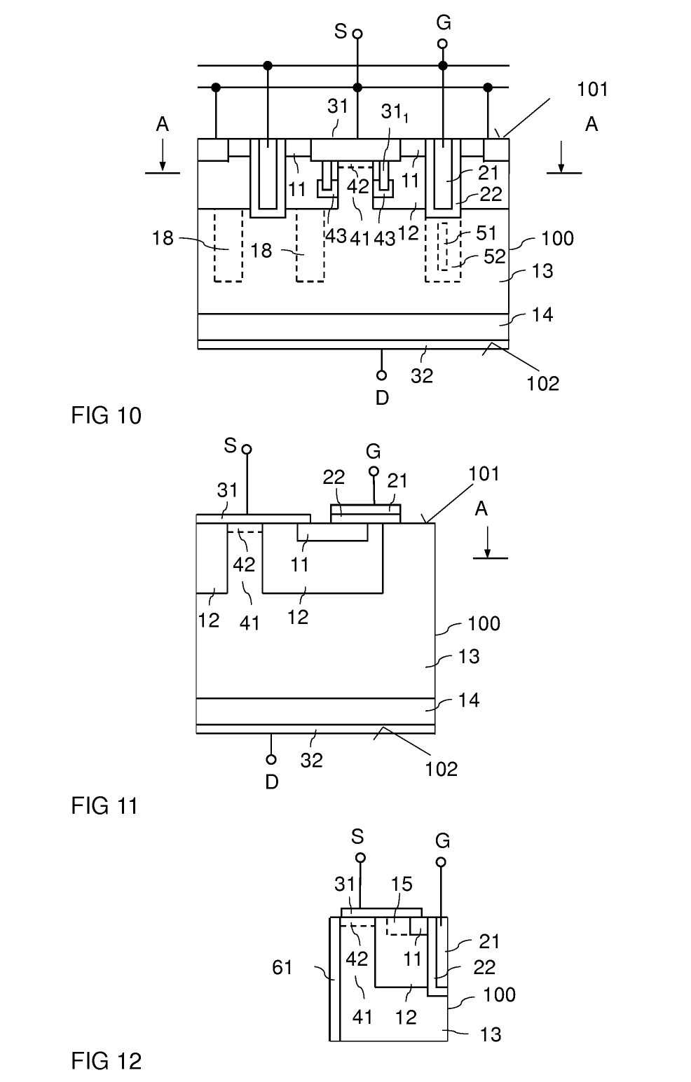

FIG. 10 illustrates a modification of the arrangement according to FIG. 9. In the arrangement of FIG. 10, the channel region 41 or the optional contact region 42 does not extend to the first surface 101 of the semiconductor body 100. In this embodiment, the semiconductor body 100 comprises a trench in the first surface 101, in which the source electrode 31 is disposed at least partially. The source electrode 31 contacts the channel region 41 or the optional contact region 42 at the bottom of the trench and the source region 11 along the side walls of the trench.

Referring to the previous explanations is the basic principle, a normally-off JFET is provided in parallel with a MOSFET, the MOSFET is not limited to a trench MOSFET. FIG. 11 illustrates a vertical cross section of a semiconductor device with a MOSFET having a planar gate electrode 21, wherein the gate electrode 21 is disposed above the first surface 101 of the semiconductor body 100. In this embodiment, the drift region 13 extends to the first surface 101 of the semiconductor body 100 to a first side of the body region 12, wherein the channel region 41 and the optional area of contact 42 along a second side opposite the first side of body region 12 of the drift region 13 extend up to the source electrode 31.

In the above-described embodiments, the channel region 41 forms two pn junctions 12 with the body region, said depletion regions can extend from the pn junctions which are formed on opposite sides of the channel region 41. However, this is merely an example.

FIG. 12 illustrates an embodiment in which the channel region 41 which adjoins one side of the body region 12 and adjoins an insulating layer 61, such as an oxide layer, on the other side. In this embodiment, only one pn-junction between the channel region 41 and the body region 12 is present. In this embodiment, a channel width d is chosen to be less than a width of the depletion region intrinsic to cutoff the channel region 41 when the MOSFET is not biased.

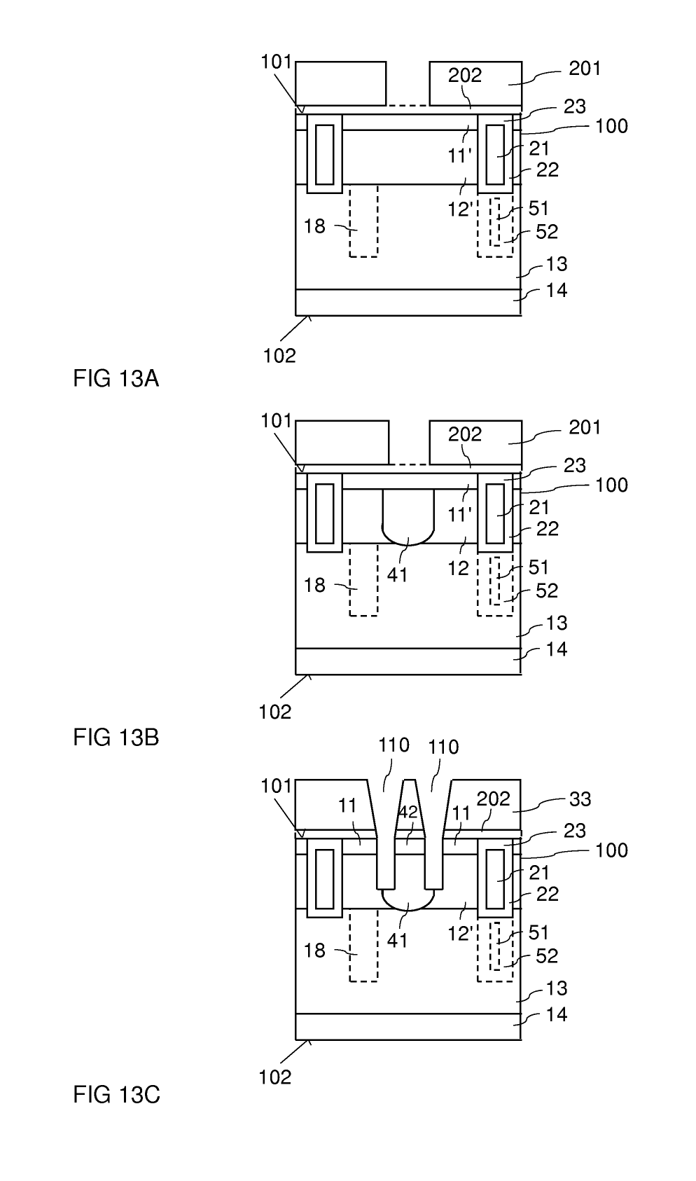

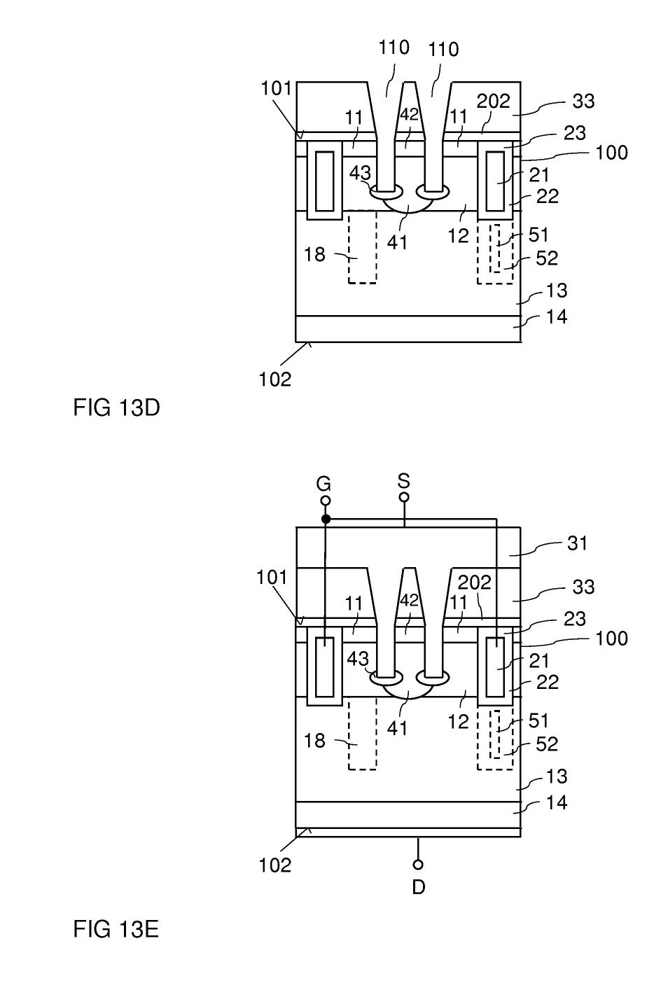

FIG. 13 which includes FIGS. 13A to 13E, illustrates a method of manufacturing a semiconductor device having a MOSFET and a JFET, or for the production of a MOSFET with integrated channel region corresponding to FIG. 9, that is for producing a semiconductor device, wherein the JFET, one of the channel region 41 adjoining depletion region 43 is spaced from the gate dielectric 22 and includes the source zone 11. FIGS. 13A to 13E each shows a vertical cross-section through the semiconductor body 100 during various steps of the manufacturing process.

Referring to FIG. 13A, first, the method comprises providing a semiconductor body 100 with a drift region 13 of first conductivity type, one of the vertical direction of the semiconductor body 100 to the drift region 13 adjacent body region 12 of the second conductivity type and in the vertical direction of the semiconductor body 100 to body region 12 subsequent source region 11 of the first conduction type. The source region 11 is adjacent to the embodiment of FIG. 13A to the first (front) surface of the semiconductor body 101 to 100. The semiconductor body 100 also includes at least one gate electrode 21, which is disposed in the example of FIG. 13A in a trench of the semiconductor body 100, and this groove from the front side 101 through the source region 11 and the body region 12 extends into the drift region 13. The gate electrode 21 is, compared with the surrounding dielectric, isolated semiconductor regions by a gate dielectric 22. Optionally, above the gate electrode 21, i.e. between the gate electrode 21 and the front side 101 of the semiconductor body, an insulating layer 23 is present.

Referring to FIG. 13A, the semiconductor body 100 further comprises a drain region 14, which is arranged in the region of the rear side 102 of the semiconductor body 100. Optionally, a field electrode 51 may be present, which is isolated by a field electrode dialectic 52 dielectrically on the drift region 13 and which is either electrically connected to the gate electrode 21, or is (31 in FIG. 13E) connected to one another to manufacture source electrode. This field plate may be positioned (as illustrated) below the gate electrode 12, but may also be arranged offset laterally to the gate electrode 21.

The arrangement shown in FIG. 13A, with the drain region 14, the drift region 13, the body region 12 and source region 11, which are successively arranged in the vertical direction of the semiconductor body between the back 102 and the front 101, to the trench gate electrode 21 and the optional field electrode 51 is a basic structure for vertical MOSFET, especially for vertical power MOSFET. The preparation of such a basic structure is generally known. Possible methods for their preparation are outlined briefly below for a better understanding.

In one embodiment for the preparation of the semiconductor body 100 as shown in FIG. 13A is provided to manufacture a doped semiconductor substrate of the first conductivity type, which forms the subsequent drain region 14, and this semiconductor substrate 14 by an epitaxial drift region 13, body region 12 and the source region 11. The individual component zones are thereby endowed during the epitaxial growth in situ. The substrate can be prepared starting from the back after the epitaxy, or after further process step starting be thinned from the back side.

Alternatively it is possible, on the semiconductor substrate, that provides the drain region 14, is to produce an epitaxial layer of the first conductivity type, having a basic doping, corresponding to the doping of the later drift region 13 and the front side 101 of dopants of the second conductivity type for in this epitaxial layer, the preparation of the Body region 12 and be introduced into the near-surface region of the first conductivity type dopants for producing the source region 11. The optional compensation regions 18 can be produced during the epitaxial growth in the drift region 13.

In another embodiment is provided to provide a semiconductor substrate available, which has a basic doping, corresponding to the doping of the subsequent drift region 13 and introduce to this semiconductor substrate 102 on the rear side of dopants of the first conductivity type to produce the drain region 14 and the first side 101 dopants of the second conductivity type to produce the body region 12 of the first conductivity type for the preparation of the source region 11.

The gate electrode 21 and the gate dielectric 22, and the field electrode 51 and the optional field electrode dielectric 52 can be manufactured in a basically known manner, in a trench, which is produced starting from the front side 101 of the semiconductor body 100.

Referring to FIG. 13A, an implant mask 201 is formed above the front side 101 of the semiconductor body 100. Optionally, before forming the implantation mask 201, a diffusion layer 202, such as a screen oxide produced above the first side of the one hundred and first is arranged. The implantation mask 201 has a recess 203, which is spaced above the source region 11 and body region 12 and arranged in the lateral direction of the semiconductor body 100 to at least one gate electrode 12.

Referring to FIG. 13B, in the next steps, dopant atoms of the first conductivity type are introduced via the recess 203 of the implantation mask 201 in such a manner in the body region 12 that, in the body region 12 between the source region 11 and the drift region 13, a channel region 41 of the first conductivity type is formed, which in the lateral direction of the semiconductor body 100 is spaced apart to the gate dielectric 22. To produce an re-channel JFET, that is a JFET with an n-doped channel region 41 (P), for example, arsenic (As) or phosphorus is implanted in the body region. In one embodiment, multiple implantation steps are carried out with different implantation energies to introduce dopant atoms from the front 101 to different depths in the body region 12, thereby to generate the ranging from the source area 11 up to the drift region 13 channel region 41. The implantation dose at which the dopants are placed is chosen so that the existing doping of the body region 12 in the area where the channel region 41, more than compensated for, and that the channel region 41 is formed with a net dopant concentration of the first conductivity type is made. This net dopant concentration of the channel region 41 and the dopant concentration of the drift region 13 may match, but the net dopant concentration of the channel region 41 may be higher or lower than the doping concentration of the drift region 13.

To activate the implanted dopant atoms a temperature processes carried out in which the semiconductor body is heated at least in the area of body region 12 to a suitable activation of the introduced dopant activation temperature. The process temperature is, for example, an RTP (rapid thermal processing) method. This temperature process can be carried out after introduction of the dopant and before carrying out further steps. In another embodiment is provided to perform the temperature method only after another, still below illustrated steps.

In the next steps, which are shown in the results in FIG. 13C, the implantation mask 201 is removed and an etching mask 33 is made above the front side 101, and possibly on the optional diffuser layer 202. This etching mask 33 comprises for example an electrical insulating material such as an oxide. In one embodiment, the etching mask 33 is an oxide hard mask.

Referring to FIG. 13C, the etching mask 33 is patterned, and using the patterned etch mask 33, a trench 110 is at least formed such that the at least one trench, and the channel region 41, extends through the source region 11 in the body region 12 and, having a first side wall, adjacent to the trench 110, the channel region 41 and the first side wall has a second opposite side wall of the groove 110 adjacent to the body region 12. The at least one trench 110 ends above the drift region 13, i.e. a bottom of the trench 110 is spaced from the drift region 13. In another embodiment (not shown) extends to the bottom of the trench 13 to the drift region.

In the embodiment illustrated in FIG. 13, the semiconductor body 100 has two gate electrodes 21, that is two gate electrode portions 21, which are arranged in the lateral direction of the semiconductor body at a distance to each other. These two gate electrodes or gate electrode portions can each be strip-shaped (FIG. 4) (FIGS. 5 and 6), or may each be columnar, be part of a gate electrode having the shape of a rectangular grid or a hexagonal grid in plan view (FIGS. 7 and 8). The geometry of the at least one trench 110 is formed at the boundary between the channel region 41 and the body region 12, depending on the geometry of the channel region 41 and the geometry of the body region 12.

If the channel region 41 and the body region 12, are for example strip-shaped, as shown in FIG. 4, so stripe-shaped trenches 110 along the interface between the channel region 41 and the left and right of the channel region 41 adjacent body region 12 can be produced. If the channel region 41, for example, are lattice-shaped, as shown in FIGS. 5 and 6, the grooves 110 that are made, (in the horizontal plane) are lattice-shaped in plan view. And the channel regions 41 are columnar, as shown in FIGS. 7 and 8, the at least one trench 110 is annular in plan view and surrounds the channel region along the boundary between the channel region 41 and the body region 12.

The depletion region 43 are made, referring to FIG. 13D, in the next process steps in the bottom of the at least one trench 110, specifically at least in the channel region 41. In the example shown in FIG. 13D, the depletion region 43 is produced both in the channel region 41, where it largely determines the operation of the JFET 12 in the body region. The depletion region 43 is—as well as the channel region 41—spaced from the gate dielectric 22, so that neither the channel 41 nor the depletion region 43 influences the control operation of the MOSFET.

The preparation of the depletion region control 43 includes, for example an implantation method, the dopant atoms are implanted in the first conductivity type in the bottom of the at least one trench. In another embodiment, the bottom of the at least one trench is filled with a dopant of the first conductivity type material and comprising dopant atoms are diffused from this material in the surrounding semiconductor regions.

If the dopant atoms of the depletion control region 43, inserted through an implantation process, may be activated by a temperature process. In one embodiment of the method, immediately after introduction of the dopant atoms for producing the channel region 41 to dispense with a temperature process, and carry out the temperature process for activating after introduction of the dopant atoms for producing the depletion control region 43, thereby previously for the channel region 41 and to activate the depletion control region 43 dopant atoms.

Referring to FIG. 13E, a source electrode 31 is then produced in the at least one trench. The source electrode 31 contacts the depletion control region 43 at the bottom of the trench, and the body region 12 and source region 11 respectively to the side wall, which faces the gate dielectric 22. Furthermore, in the at least one trench 31, the source electrode contacts the channel region 41 and a contact zone 42 of the first conductivity type. The contact zone 42 ensures that the channel zone 41 is connected via an ohmic contact to the source electrode 31. The source electrode 31 may be formed by depositing a single layer of material or by depositing a plurality of layers of material. In one embodiment, there is provided first to fill the at least one trench with a first material such as a highly doped polycrystalline semiconductor material such as polysilicon or a metal, such as titanium (Ti), titanium nitride (TiN) or tungsten (W), and then a further electrode layer, such as a metal, for example, copper (Cu), aluminum (Al) or an aluminum-copper alloy to deposit on the electrode layer previously prepared. Alternatively, the trench more of the above materials are filled with a layer stack composed of two or more.

The etching mask 33 is used in the process described also as an insulating layer, the source electrode 31, the distance to the at least one trench to the semiconductor regions of the semiconductor body isolation. The etching mask 33, the source electrode 31 and isolated from the gate electrode 21. To electrically connect the gate electrode 21 connected to a gate terminal G (shown only schematically in FIG. 13E), may be etched, for example, contact holes (not shown) in the source electrode 31 and insulating layer 33. In further embodiments, particularly in embodiments in which each gate electrode portions 21 are formed in a strip shape, it is provided that the individual strips projecting at the edges of the source electrode 31 of the source electrode 31, where they can be contacted in a suitable manner. This is a principle known procedure that can be waiving any other versions.

In the semiconductor device shown in FIG. 13E, the channel region 41 is partially separated by the disposed in the at least one groove portion of the source electrode 31 from the body region, the channel region 41 adjacent the body region under the depletion control region 43. However, this is only an example. Control the depletion region 43 may also be realized so that it extends to the drift region 13. In this case, the channel region 41 is not adjacent to the body region.

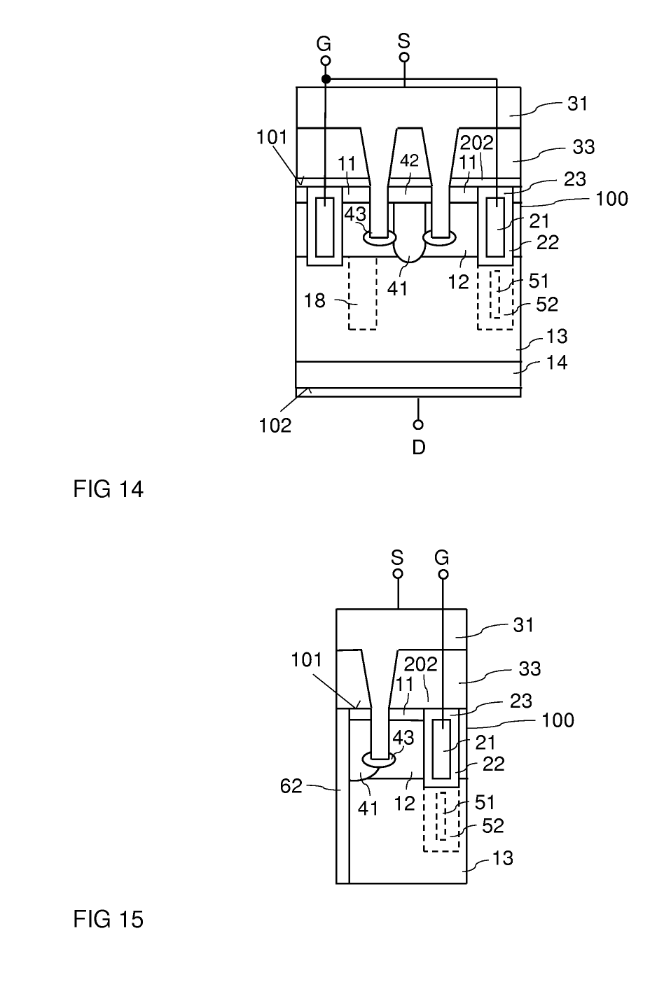

FIG. 14 shows a shows a vertical cross section through a component according to another embodiment. This device differs from the device according to FIG. 13E in that the trench with a source electrode 31 is disposed entirely within of at least the body region 12 so that both sides of the body region are adjacent the trench. The depletion control region 43 extends to or into the channel region.

The device of FIG. 14 can be produced in accordance with the FIGS. 13A to 13E. In another example, in accordance with FIG. 13C, a trench 110 is not separated at the interface between the channel region 41 and the body region 12, but at least is made to this interface in the body region 12. The trench depth can be chosen so that the depletion region produced on control grave base 43 extends up to the drift region 13 and is spaced from the drift region.

FIG. 15 shows a vertical cross section through portion of a semiconductor device prepared by a modification of the method described with reference to FIGS. 11A to 11E. The JFET device shown in FIG. 14 is formed along an insulating layer 62 which is spaced to the gate dielectric 22. This device can be constructed so that the channel region 41 is initially made along the insulation layer 62 between the source region 11 and the drift region 13 and in that then, along the boundary between the channel region 41 and the body region 12 of the trench is prepared in which then, in the bottom region, the depletion control region 43 is made.

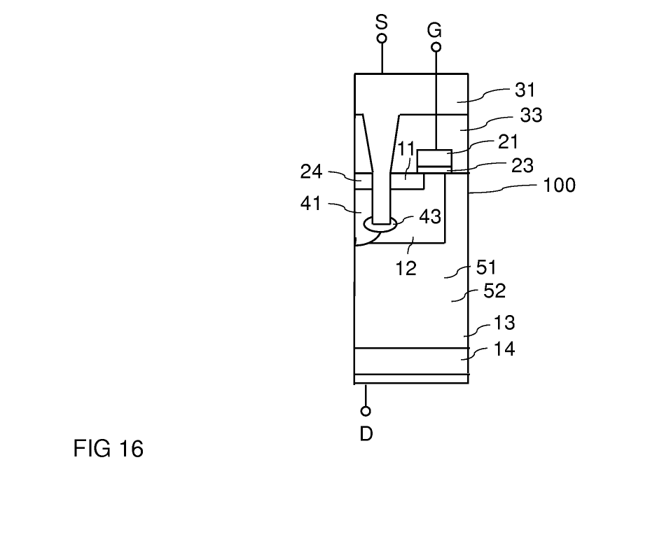

FIG. 16 shows a cross section through a semiconductor device according to another embodiment. In this embodiment, the gate electrode 21 is formed as a planar electrode 101 above the front side of the semiconductor body. The method for the preparation of this component differs from the method according to the FIGS. 11A to 11E in that the beginning of the process, a semiconductor body having a planar gate electrode is provided instead of a trench gate electrode.

Although the implementations of the disclosure have been described in language specific to structural features and/or methodological acts, it is to be understood that the implementations are not necessarily limited to the specific features or acts described. Rather, the specific features and acts are disclosed as representative forms of implementing example devices and techniques.

What is claimed is:

1. A semiconductor device, comprising:
a MOSFET having a source region, a drift region and a drain region of a first conductivity type, a body region of a second conductivity type disposed between the source region and the drift region, and a gate electrode disposed adjacent to said body region, the gate electrode being isolated from the body region by a dielectric, and having a source electrode contacting the source region and the body region; and
a self-locking JFET with a channel region of the first conductivity type, the channel region connected between the source electrode and the drift region, and coupled to and adjacent the body region.

2. The semiconductor device according to claim 1, further comprising:
a depletion control region of the second conductivity type,
wherein the depletion control region has a higher doping concentration than the body region, is electrically connected to the source electrode, and is adjacent to the channel region.

3. The semiconductor device according to claim 2, further comprising:
a semiconductor body having a first surface,
wherein the depletion control region is arranged spaced from the first surface.

4. The semiconductor device according to claim 3, wherein a distance between the first surface and depletion control region is between 0.1 μm and 3 μm.

5. The semiconductor device according to claim 3, wherein a portion of the source electrode is arranged in a trench, the trench starting from the first surface and extends to the depletion control region.

6. The semiconductor device according to claim 5, wherein the trench separates the channel region from the body region.

7. The semiconductor device according to claim 1, wherein the channel region is at least partially on the body region and the channel region forms a pn junction with said body region.

8. The semiconductor device according to claim 1, further comprising:
a semiconductor body, said source region and the drain region in a vertical direction of the semiconductor body being spaced apart from one another.

9. The semiconductor device according to claim 8, wherein said channel region is positioned in a vertical direction of the semiconductor body along said body region.

10. The semiconductor device according to claim 1, wherein a doping concentration of the channel region corresponds to a doping concentration of the drift region.

11. The semiconductor device according claim 1, wherein the channel region adjoins to the drift region.

12. The semiconductor device according to claim 1, wherein the JFET has a current flow direction and the channel region has a width (d) in a direction perpendicular to the current flow direction, wherein the width (d) is between 0.1 μm and 0.8 μm.

13. The semiconductor device according to claim 1, wherein said JFETs has a current flow direction, the channel region and the body region being perpendicular to the current flow direction.

14. The semiconductor device according to claim 1, further comprising:
an insulating layer extending to the channel region on a side opposite to the body region adjoined to the channel region.

15. The semiconductor device according to claim 1, wherein JFET has a current flow direction and the channel region has a width (d) in a direction perpendicular to the direction of current flow;
an intrinsic depletion region of the pn junction between the body region and the channel region is present, when the MOSFET is in a non-biased state,
a width of the depletion region depends on an intrinsic doping concentration of the channel region, and
the doping concentration of the channel region is selected so that a width of the intrinsic depletion region is larger than the width of the channel region.

16. A MOSFET, comprising:
a semiconductor body having a source region, a drift region and a drain region having a first conductivity type and a body region having a second conductivity type, the body region being between the source region and the drift region;
a gate electrode disposed adjacent the body region, the gate electrode being isolated by a gate dielectric;
a source electrode which contacts the source region and the body region; and
a channel region of the first conductivity type extending from the source electrode to the drift region, so that a pn junction between the body region and the channel region is provided, wherein a doping concentration of the body region and a width of the channel region are such that the intrinsic depletion zone of the channel region cuts off when the MOSFET is in a non-biased state.

17. The MOSFET of claim 16, further comprising: a depletion control region of the second conductivity type, wherein the depletion control region has a higher doping concentration than the body region, is electrically connected to the source electrode and is adjacent to the channel region.

18. The MOSFET according to claim 16, wherein the JFET has a current flow direction, and wherein the channel region has a width (d) in a direction perpendicular to the current flow direction, wherein the width (d) is between 0.1 μm and 0.8 μm.

19. The MOSFET according to claim 18, wherein the body region surrounds the channel region perpendicular to the current flow direction in one direction.

20. The MOSFET according to claim 15, further comprising:
an insulating layer disposed adjacent to the channel region on an opposite side to the body region.

21. A method of manufacturing a semiconductor device, comprising:
providing a semiconductor body having a drift region of a first conductivity type, a body region having a second conductivity type that is complementary to the first conductivity type, the body region being adjacent to the drift region, a source region having the first conductivity type and adjacent to the body region, and a gate electrode adjacent to the body region, the gate electrode isolated from the body region by a gate dielectric;
forming a channel region in the body region and spaced from the gate dielectric, wherein the channel region extends up from the drift region to the source region;
producing at least one trench in the source region, the body region and the channel region, a first sidewall of the trench adjacent to the body region and a second sidewall of the trench, opposite of the first sidewall, adjacent to the channel region;
forming a depletion control region having the second conductivity type, the depletion control region being adjacent to the trench, at least in the channel region and spaced from the source region; and
forming a source electrode in the trench.

24. The method according to claim 21, wherein the gate electrode is disposed in a second trench which extends from a first side of the semiconductor body, through the source region and the body region, and into the drift region.

25. The method according to claim 21, wherein the semiconductor body has two gate electrodes or two gate electrode portions which are arranged in a horizontal direction, spaced from each other, wherein the channel region and the body region are disposed between the two gate electrodes or gate electrode portions.

24. The method according to claim 21, wherein forming the channel region comprises utilizing an implantation and/or diffusion process.

25. The method according to claim 21, wherein the producing of the at least one trench comprises using an etch mask, the etch mask remaining after forming the at least one trench.

26. The method according to claim 26, further comprising:
forming a drain region of the first conductivity type, the drain region at least spaced apart from the body region.
